(19) United States
(12) Patent Application Publication
(10) Pub. No.: US 2018/0309065 A1
(43) Pub. Date: Oct. 25, 2018

(54) CHARGE TRANSFER SALT, ELECTRONIC DEVICE AND METHOD OF FORMING THE SAME

(71) Applicants: Cambridge Display Technology Limited, Godmanchester (GB); Sumitomo Chemical Company Limited, Tokyo (JP)

(72) Inventors: Sheena Zuberi, Godmanchester (GB); Thamas Kugler, Cambridge (GB); Florence Bourcet, Godmanchester (GB)

(73) Assignees: Cambridge Display Technology Limited, Godmanchester (GB); Sumitomo Chemical Company Limited, Tokyo (JP)

(21) Appl. No.: 15/779,332

(22) PCT Filed: Nov. 24, 2016
(86) PCT No.: PCT/GB2016/053697

§ 371 Date: May 25, 2018

(30) Foreign Application Priority Data
Nov. 25, 2015 (GB) 1520826.7

(51) Int. Cl. H01L 51/00; C08G 61/02; H01L 51/50; H01L 51/56

(52) U.S. Cl. CPC H01L 51/0039; H01L 51/0003; C08G 61/02; H01L 51/5012; H01L 51/5092; C08L 2205/02; C08G 2261/1424; C08G 2261/148; C08G 2261/514; C08G 2261/95; H01L 51/56

(57) ABSTRACT

A charge-transfer salt formed from an organic semiconductor doped by a polymer comprising a first repeat unit substituted with at least one group comprising at least one n-dopant. The n-dopant may spontaneously n-dope the organic semiconductor or may n-dope the organic semiconductor upon activation. An electron-injection layer of an organic light-emitting device may comprise the n-doped semiconductor.

### FIELD OF THE INVENTION

The invention relates to n-doped organic semiconductors, methods of forming n-doped semiconductors and electronic devices containing n-doped semiconductors.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An organic light-emitting device has a substrate carrying an anode, a cathode and an organic light-emitting layer containing a light-emitting material between the anode and cathode.

In operation, holes are injected into the device through the anode and electrons are injected through the cathode. Holes in the highest occupied molecular orbital (HOMO) and electrons in the lowest unoccupied molecular orbital (LUMO) of the light-emitting material combine to form an exciton that releases its energy as light.

Cathodes include a single layer of metal such as aluminium, a bilayer of calcium and aluminium as disclosed in WO 98/10621; and a bilayer of a layer of an alkali or alkali earth compound and a layer of aluminium as disclosed in L. S. Hung, C. W. Tang, and M. G. Mason, Appl. Phys. Lett. 70, 152 (1997).

An electron-transporting or electron-injecting layer may be provided between the cathode and the light-emitting layer.

Bao et al, “Use of a 1H-Benzoimidazole Derivative as an n-Type Dopant and To Enable Air-Stable Solution-Processed n-Channel Organic Thin-Film Transistors” J. Am. Chem. Soc. 2010, 132, 8852-8853 discloses doping of [6,6]-phenyl C₆₁ butyric acid methyl ester (PCBM) by mixing (4-(1,3-dimethyl-2,3-dihydro-1H-benzoimidazol-2-yl)phenyl)dimethylamine (N-DMBI) with PCBM and activating the N-DMBI by heating.

US 2014/070178 discloses an OLED having a cathode disposed on a substrate and an electron-transporting layer formed by thermal treatment of an electron-transporting material and N-DMBI. It is disclosed that a radical formed on thermal treatment of N-DMBI may be a n-dopant.

U.S. Pat. No. 8,920,944 discloses n-dopant precursors for doping organic semiconductive materials.

Naab et al, “Mechanistic Study on the Solution-Phase n-Doping of 1,3-Dimethyl-2-aryl-2,3-dihydro-1H-benzoimidazole Derivatives”, J. Am. Chem. Soc. 2013, 135, 15018-15025 discloses that n-doping may occur by a hydride transfer pathway or an electron transfer pathway.

It is an object of the invention to provide organic electronic devices comprising n-doped layers having improved performance.

### SUMMARY OF THE INVENTION

In a first aspect the invention provides a charge-transfer salt formed from an organic semiconductor doped by a polymer comprising a first repeat unit substituted with at least one group comprising at least one n-dopant.

In a second aspect the invention provides a method of forming a charge-transfer salt according to the first aspect, the method comprising an activation step causing the n-dopant to dope the organic semiconductor.

In a third aspect the invention provides an organic electronic device comprising a layer comprising a charge-transfer salt according to any preceding claim.

In a fourth aspect the invention provides a method of forming an organic electronic device according to the third aspect wherein the layer comprising the charge-transfer salt is formed by forming a layer comprising or consisting of a mixture of the organic semiconductor and the polymer, or comprising or consisting of a polymer comprising a first repeat unit in a backbone of the polymer substituted with at least one group comprising at least one n-dopant a polymer and an organic semiconductor repeat unit in the polymer backbone, and activating the layer to cause the n-dopant to dope the organic semiconductor.

In a fifth aspect the invention provides a polymer comprising a repeat unit of formula (I):

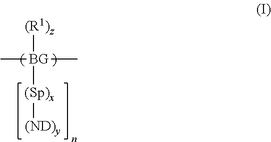

wherein:
BG is a backbone group;
Sp is a spacer group;
ND is an n-dopant;
R¹ is a substituent;
x is 0 or 1;
y is at least 1; and
z is 0 or a positive integer; and
n is at least 1.

In a sixth aspect the invention provides a method of forming a polymer according to the fifth aspect, the method comprising the step of reacting a precursor polymer comprising a reactive repeat unit of formula (Ir) with a compound of formula ND-Y

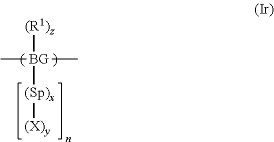

wherein X is a reactive group or wherein Sp-X comprises a reactive group; and Y is a reactive group.

### DESCRIPTION OF THE DRAWINGS

The invention will now be described in more detail with reference to the drawings in which:

FIG. 1 illustrates schematically an OLED according to an embodiment of the invention; and

FIG. 2 is a graph of current density vs. voltage for electron-only devices comprising charge-transfer salts according to embodiments of the invention and for a comparative device.

### DETAILED DESCRIPTION OF THE INVENTION

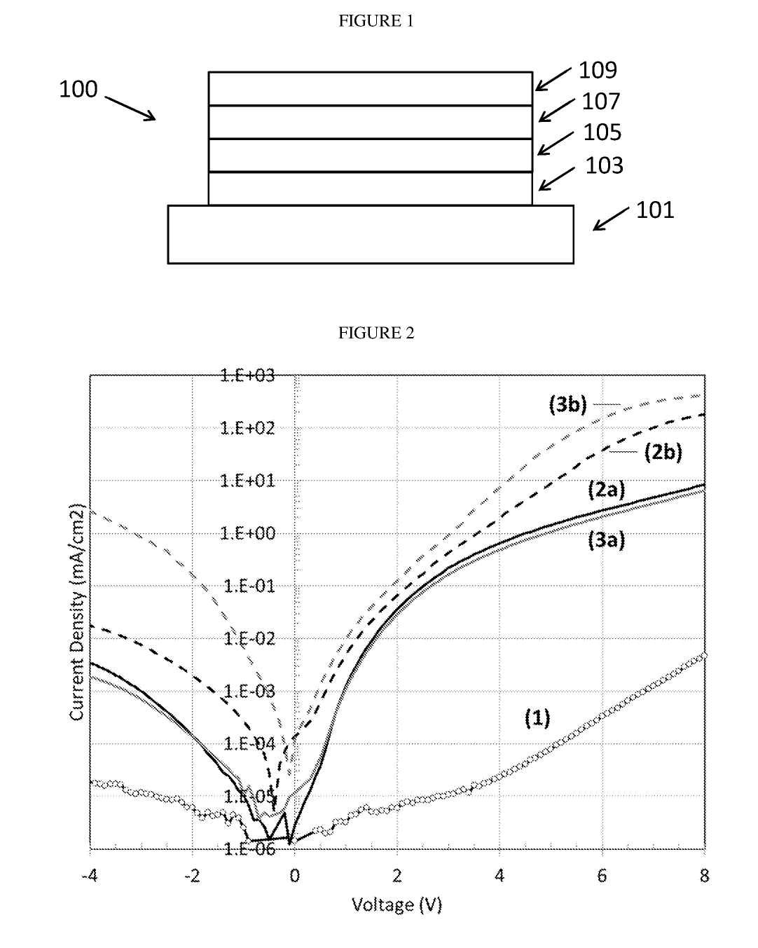

FIG. 1, which is not drawn to any scale, illustrates an OLED 100 according to an embodiment of the invention supported on a substrate 101, for example a glass or plastic substrate. The OLED 100 comprises an anode 103, a light-emitting layer 105, an electron-injecting layer 107 and a cathode 109.

The anode 103 may be single layer of conductive material or may be formed from two or more conductive layers. Anode 103 may be a transparent anode, for example a layer of indium-tin oxide. A transparent anode 103 and a transparent substrate 101 may be used such that light is emitted through the substrate. The anode may be opaque, in which case the substrate 101 may be opaque or transparent, and light may be emitted through a transparent cathode 109.

Light-emitting layer 105 contains at least one light-emitting material. Light-emitting material 105 may consist of a single light-emitting compound or may be a mixture of more than one compound, optionally a host doped with one or more light-emitting dopants. Light-emitting layer 105 may contain at least one light-emitting material that emits phosphorescent light when the device is in operation, or at least one light-emitting material that emits fluorescent light when the device is in operation. Light-emitting layer 105 may contain at least one phosphorescent light-emitting material and at least one fluorescent light-emitting material.

Electron-injecting layer 107 comprises or consists of a charge-transfer complex formed from an organic semiconductor doped by a polymer comprising a backbone comprising a first repeat unit substituted with one or more groups comprising an n-dopant. The charge transfer complex may be formed from a mixture of the polymer material and a separate organic semiconductor material or the polymer may comprise the first repeat unit substituted with one or more groups comprising an n-dopant and a backbone repeat unit capable of accepting a hydride group or electron from the n-dopant.

Cathode 109 is formed of at least one layer, optionally two or more layers, for injection of electrons into the device.

Preferably, the electron-injecting layer 107 is in contact with organic light-emitting layer 105. Preferably, the film of the organic semiconductor and polymer substituted with n-dopants is formed directly on organic light-emitting layer 105.

Preferably, the organic semiconductor has a LUMO that is no more than about 1 eV, optionally less than 0.5 eV or 0.2 eV, deeper than a LUMO of a material of the light-emitting layer, which may be a LUMO of a light-emitting material or a LUMO of a host material if the light-emitting layer comprises a mixture of a host material and a light-emitting material. Optionally, the doped organic semiconductor has a work function that is about the same as a LUMO of a material of the light-emitting layer. Optionally, the organic semiconductor has a LUMO of less than 3.0 eV, optionally around 2.1-2.8 eV.

Preferably, the cathode 109 is in contact with the electron-injecting layer 107.

Preferably, the cathode is formed directly on the film of the organic semiconductor and polymer comprising n-doping substituents.

The OLED 100 may be a display, optionally a full-colour display wherein the light-emitting layer 105 comprises pixels comprising red, green and blue subpixels.

The OLED 100 may be a white-emitting OLED. White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K. A white-emitting OLED may contain a plurality of light-emitting materials, preferably red, green and blue light-emitting materials, more preferably red, green and blue phosphorescent light-emitting materials, that combine to produce white light. The light-emitting materials may all be provided in light-emitting layer 105, or one or more additional light-emitting layers may be provided.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

The photoluminescence spectrum of a material may be measured by casting 5 wt % of the material in a PMMA film onto a quartz substrate to achieve transmittance values of 0.3-0.4 and measuring in a nitrogen environment using apparatus C9920-02 supplied by Hamamatsu.

The OLED 100 may contain one or more further layers between the anode 103 and the cathode 109, for example one or more charge-transporting, charge-blocking or charge-injecting layers. Preferably, the device comprises a hole-injection layer comprising a conducting material between the anode and the light emitting layer 105. Preferably, the device comprises a hole-transporting layer comprising a semiconducting hole-transporting material between the anode 103 and the light emitting layer 105.

“Conducting material” as used herein means a material having a work function, for example a metal or a doped semiconductor.

“Semiconductor” as used herein means a material having a HOMO and a LUMO level, and a semiconductor layer is a layer comprising a semiconducting material or consisting of one or more semiconducting materials.

The electron-injecting layer is formed by forming a layer of a polymer having n-dopant in side-chains thereof that is either mixed with an organic semiconductor acceptor material or that comprises acceptor repeat units in the polymer backbone. The electron-injecting layer may consist of this polymer with acceptor repeat units in the polymer backbone or mixture of this polymer with an organic semiconductor material, or it may comprise one or more further materials.

The n-dopant may spontaneously dope the acceptor material to form a charge-transfer salt, or n-doping may occur upon activation, for example heat or irradiation of the n-dopant and acceptor. The electron-injecting layer may comprise or consist of the charge-transfer salt.

In forming the electron-injecting layer, the organic semiconductor and polymer substituted with n-dopants may be deposited in air.

In forming the electron-injecting layer, the polymer substituted with n-dopants and the organic semiconductor (which may be provided as a repeat unit in the polymer backbone or as a separate material mixed with the polymer) may be deposited from a solution in a solvent or solvent mixture. The solvent or solvent mixture may be selected to prevent dissolution of the underlying layer, such as an underlying organic light-emitting layer 105 or the underlying layer may be crosslinked.

The polymer comprises a backbone comprising a first repeat unit substituted with one or more groups comprising an n-dopant.

All of the repeat units of the polymer backbone may be first repeat units, or the polymer backbone may comprise one or more further repeat units that are not substituted with one or more groups comprising an n-dopant. If further repeat units are present then the first repeat units may form between 0.1-99 mol % of the repeat units of the polymer, optionally 0.1-50 mol %, optionally 1-30 mol %.

The first repeat unit may be substituted with one or more, optionally 1-4, groups comprising an n-dopant. The one or more groups comprising an n-dopant may be the only substituents of the first repeat unit or the first repeat unit may be substituted with one or more further substituents.

Further repeat units, if present, may be unsubstituted or substituted with one or more substituents.

Further substituents of the first repeat unit and substituents of any further repeat units may be selected to control the solubility of the polymer. Preferred substituents for solubility of the polymer in non-polar solvents are C₁₋₄₀ hydrocarbyl groups, preferably C₁₋₂₀ alkyl groups and phenyl substituted with one or more C₁₋₁₀ alkyl groups. Preferred substituents for solubility of the polymer in polar solvents comprise substituents containing one or more ionic groups, optionally carboxylate groups, and/or one or more ether groups, optionally a substituent comprising a group of formula —(OCH₂CH₂)ₙ— wherein n is at least 1, optionally an integer from 1 to 10.

The groups forming the polymer backbone may be conjugated groups or non-conjugated groups. Conjugated groups in the polymer backbone may be conjugated to one another to form a conjugated polymer backbone.

The first repeat unit may be a repeat unit of formula (I):

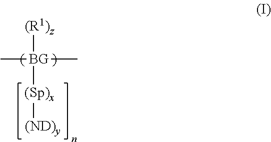

wherein:
BG is a backbone group;
Sp is a spacer group;
ND is an n-dopant;
R¹ is a substituent;
x is 0 or 1;
y is at least 1, optionally 1, 2 or 3;
z is 0 or a positive integer, optionally 0, 1, 2 or 3; and
n is at least 1, optionally 1, 2 or 3.

The or each further repeat unit, if present, may be a repeat unit of formula (II):

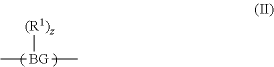

wherein:
BG is a backbone group;
R¹ is a substituent; and
z is 0 or a positive integer, optionally 0, 1, 2 or 3.
n-dopants as described herein may be electron donors or hydride donors.

In the case where ND is an n-dopant that dopes the organic semiconductor spontaneously, it is optionally an n-dopant having a HOMO or semi-occupied molecular orbital (SOMO) level that is shallower (closer to vacuum) than the LUMO level of the organic semiconductor. Preferably, the n-dopant has a HOMO level that is at least 0.1 eV shallower than the LUMO level of the organic semiconductor, optionally at least 0.5 eV. In this case, the n-dopant is preferably an electron donor.

HOMO and LUMO levels as described herein are as measured by square wave voltammetry.

In the case where ND is an n-dopant that dopes the organic semiconductor upon activation, the n-dopant has a HOMO level that is the same as or, preferably, deeper (further from vacuum) than the LUMO level of the organic semiconductor, optionally at least 1 eV or 1.5 eV deeper than the LUMO level of the organic semiconductor. Accordingly, little or no spontaneous doping occurs upon mixing of the organic semiconductor and such an n-dopant at room temperature, and little or no spontaneous doping by ND occurs if the organic semiconductor is provided as a repeat unit of the polymer backbone. An n-dopant may be a hydride donor. An n-dopant may be a material that is capable of converting to a radical that can donate an electron from a SOMO level.

Exemplary n-dopants comprise a 2,3-dihydro-benzoimidazole group, optionally a 2,3-dihydro-1H-benzoimidazole group.

The n-dopant is preferably a group of formula (III):

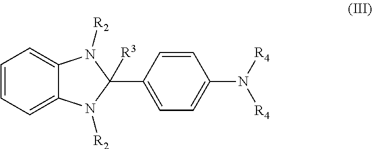

wherein:
each R² is independently a C₁₋₂₀ hydrocarbyl group, optionally a C₁₋₁₀ alkyl group;
R³ is H or a C₁₋₂₀ hydrocarbyl group, optionally H, C₁₋₁₀ alkyl or C₁₋₁₀ alkylphenyl; and
each R⁴ is independently a C₁₋₂₀ hydrocarbyl group, optionally C₁₋₁₀ alkyl, phenyl or phenyl substituted with one or more C₁₋₁₀ alkyl groups.

Exemplary n-dopants include the following:

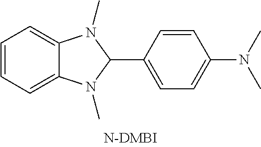 [SMILES: CN(C)c1ccc(C2N(C)c3ccccc3N2C)cc1]

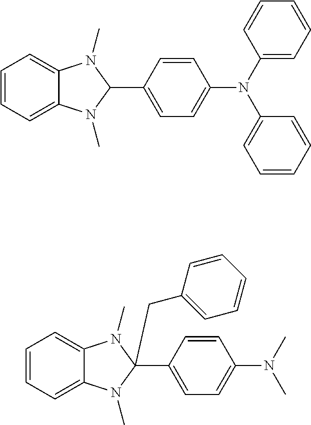 [SMILES: CN1c2ccccc2N(C)C1c1ccc(N(c2ccccc2)c2ccccc2)cc1 ; CN(C)c1ccc(C2(Cc3ccccc3)N(C)c3ccccc3N2C)cc1]

N-DMBI is disclosed in Adv. Mater 2014, 26, 4268-4272, the contents of which are incorporated herein by reference.

The n-dopant of formula (III) may be bound to BG or Sp through any available carbon atom. Exemplary n-dopant groups ND include the following:

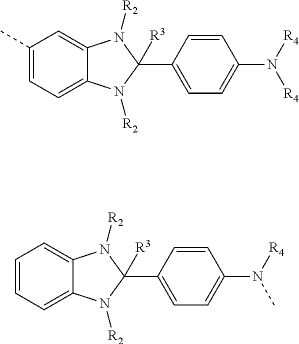

wherein --- is a bond to the backbone group BG or, if present, spacer group Sp of formula (I).

Other exemplary n-dopants are leuco crystal violet disclosed in J. Phys. Chem. B, 2004, 108 (44), pp 17076-17082, the contents of which are incorporated herein by reference, and NADH.

The spacer group Sp, if present, may be a group of formula —(X)a-(Y)b-(Z)c- such that the repeat unit of formula (I) has formula (Ia):

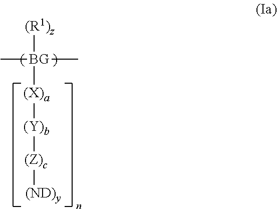

wherein:
X and Z are each independently selected from the group consisting of C₁₋₂₀ alkylene wherein one or more non-adjacent C atoms may be replaced with O, S, CO and COO;
Y independently in each occurrence is C₆₋₂₀ arylene, preferably phenylene, that may be unsubstituted or substituted with one or more substituents, optionally one or more C1-10 alkyl groups; and
a is 0 or 1;
b is 0 or a positive integer, optionally 1, 2 or 3; and
c is 0 or 1,
   with the proviso that at least one of a, b and c is at least 1.

Preferred spacer groups Sp are:
spacer groups of formula X, optionally C₁₋₂₀ alkylene, C₁₋₂₀alkoxylene or C₁₋₂₀ oxyalkylene; and
spacer groups of formula Y—Z, optionally phenylene-C₁₋₂₀ alkylene, phenylene-C₁₋₂₀ alkoxylene and phenylene-C₁₋₂₀ oxyalkylene wherein the phenylene group is unsubstituted or substituted.

Substituents R¹ of formula (I) or formula (II), if present, may be the same or different in each occurrence and may independently be selected from the group consisting of:

### D;

alkyl, optionally C₁₋₂₀ alkyl, wherein one or more non-adjacent C atoms may be replaced with a group selected from: C₆₋₂₀ aryl or C₆₋₂₀ arylene, optionally phenyl, that is unsubstituted or substituted with one or more substituents, 5-20 membered heteroaryl or 5-20 membered heteroarylene that is unsubstituted or substituted with one or more substituents, O, S, C═O or —COO; or
a group of formula —(Ar¹)ₙ wherein Ar¹ in each occurrence is independently a C₆₋₂₀ aryl or 5-20 membered heteroaryl group that is unsubstituted or substituted with one or more substituents and n is at least 1, optionally 1, 2 or 3.

An aryl, arylene, heteroaryl or heteroarylene group of a substituent R¹ may be unsubstituted or substituted with one or more substituents. Substituents, where present, may selected from C₁₋₂₀ alkyl wherein one or more non-adjacent C atoms may be replaced with O, S, C═O or —COO—, more preferably C₁₋₂₀ alkyl.

The substituent or substituents R¹ of a first repeat unit and/or of a further repeat unit may be selected according to the required solubility of the polymer. Preferred substituents for solubility of the polymer in non-polar solvents are C₁₋₄₀ hydrocarbyl groups, preferably C₁₋₂₀ alkyl groups and phenyl substituted with one or more C₁₋₁₀ alkyl groups. Preferred substituents for solubility of the polymer in polar solvents are substituents containing one or more ether groups, optionally a substituent comprising a group of formula —(OCH₂CH₂)ₙ— wherein n is at least 1, optionally an integer from 1 to 10; groups of formula —COOR¹⁰ wherein R¹⁰ is a C₁₋₅ alkyl group; and ionic substituents. Ionic substituents may be cationic or anionic. Exemplary cationic substituents comprise formula —COO⁻M⁺ wherein M⁺is a metal cation, preferably an alkali metal cation. Exemplary anionic substituents comprise quaternary ammonium.

A polymer comprising ester substituents may be converted to a polymer comprising a group of formula —COO⁻M⁺. The conversion may be as described in WO 2012/133229, the contents of which are incorporated herein by reference.

The backbone group BG of the repeat units of formula (I) is preferably a C₆₋₃₀ arylene group, optionally a group selected from fluorene, phenylene, naphthalene, anthracene, indenofluorene, phenanthrene and dihydrophenanthrene repeat units.

The backbone group BG of the repeat units of formula (II), if present, are preferably selected from C₆₋₃₀ arylene groups as described above with reference to repeat units of formula (I) or a repeat unit capable of accepting a hydride group or an electron from the n-dopant, for example repeat units as described with reference to the organic semiconductor.

In the case where the polymer is mixed with the organic semiconductor, the polymer backbone preferably is not doped by the n-dopant (either spontaneously or upon activation). Preferably, the polymer backbone has a LUMO level of no more than about 2.3 eV from vacuum level. The LUMO level of the polymer backbone may be determined by cyclic voltammetry of the polymer in which the n-dopant group is absent.

Each arylene repeat unit of formula (I) is substituted with at least one group of formula -(Sp)ₓ(ND)_{y}. The group of formula -(Sp)ₓ-(ND)_{y} may be the only substituent or substituents of the repeat unit of formula (I) or the repeat unit of formula (I) may be further substituted with one or more substituents R¹.

Each arylene repeat unit of formula (II) may be unsubstituted or may be substituted with one or more substituents R¹.

Exemplary arylene repeat units forming the backbone group BG of repeat units of formula (I) or (II) are repeat units of formulae (IV)-(VII):

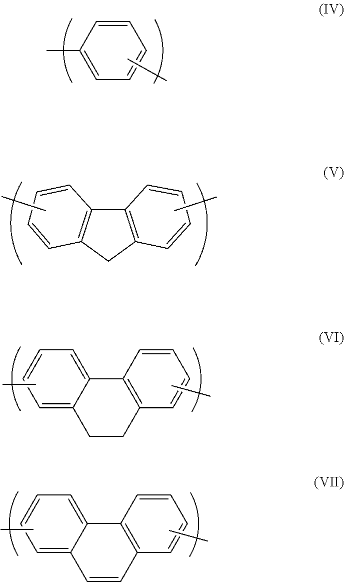

wherein n is 1, 2 or 3.

If n of formula (IV) is 1 then exemplary repeat units of formula (IV) include the following:

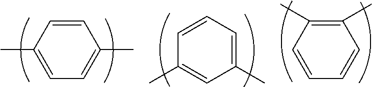

Exemplary repeat units where n is 2 or 3 include the following:

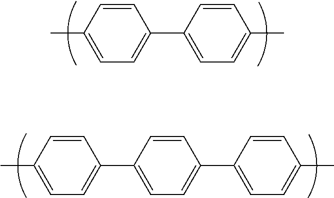

A particularly preferred repeat unit of formula (V) has formula (Va):

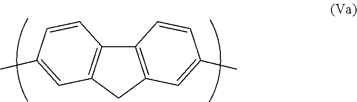

Exemplary repeat units of formula (I) include the following:

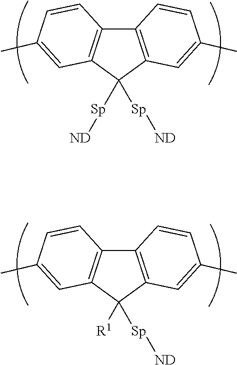

Exemplary repeat units of formula (II) include the following:

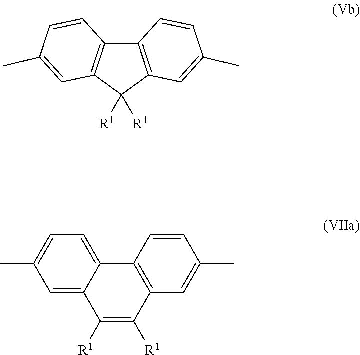

### Organic Semiconductor

The organic semiconductor is n-doped by the n-dopant, either spontaneously on contact of the organic semiconductor and the n-dopant or upon activation. If no, or limited, spontaneous n-doping occurs then the extent of n-doping may be increased by activation.

The organic semiconductor may be a polymeric or non-polymeric material, and may be provided as a backbone repeat unit of the polymer substituted with n-dopants. Optionally, the organic semiconductor is a polymer, more preferably a conjugated polymer.

The organic semiconductor comprises a polar double or triple bond, optionally a bond selected from a C═N group, a nitrile group or a C═O group, particularly in the case wherein the n-dopant is a hydride donor.

Preferably, these polar double- or triple-bond groups are conjugated to a conjugated polymer backbone.

The organic semiconductor may comprise benzothiadiazole units. The benzothiadiazole units may be units of a polymer that is mixed with the polymer substituted with an n-dopant or a repeat unit in the backbone of the polymer substituted with an n-dopant. A polymeric repeat unit may comprise or consist of repeat units of formula:

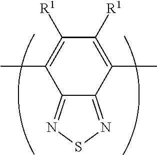

wherein R¹ in each occurrence is a substituent, optionally a substituent selected from alkyl, optionally C₁₋₂₀ alkyl, wherein one or more non-adjacent C atoms may be replaced with optionally substituted aryl or heteroaryl, O, S, C═O or —COO—, and one or more H atoms may be replaced with F.

A repeat unit comprising benzothiadiazole may have formula:

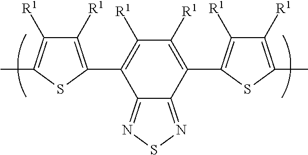

wherein R¹ is as described above with reference to benzothiadiazole.

A polymer that is mixed with the polymer comprising an n-dopant may comprise repeat units comprising benzothiadiazole repeat units and one or more arylene repeat units.

Arylene repeat units include, without limitation, fluorene, phenylene, naphthalene, anthracene, indenofluorene, phenanthrene and dihydrophenanthrene repeat units, each of which may be unsubstituted or substituted with one or more substituents. Arylene repeat units may be selected from repeat units of formulae (IV)-(VII) as described above.

The polymer comprising a first repeat unit substituted with an n-dopant may comprise an acceptor repeat unit in the polymer backbone, optionally an acceptor repeat unit comprising a polar double or triple bond as described herein.

Polymers as described anywhere herein, including polymers substituted with an n-dopant and semiconductor polymers, suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of polymers described anywhere herein may be 1×10³ to 1×10⁸, and preferably 1×10⁴ to 1×10⁷.

Polymers as described anywhere herein are suitably amorphous polymers.

### Polymer Formation

If the polymer is a conjugated polymer then the polymer may be formed by polymerising monomers comprising leaving groups that leave upon polymerisation of the monomers to form conjugated repeat units. Exemplary polymerization methods include, without limitation, Yamamoto polymerization as described in, for example, T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference and Suzuki polymerization as described in, for example, WO 00/53656, the contents of which are incorporated herein by reference.

Preferably, the polymer is formed by polymerising monomers comprising boronic acid or boronic ester group leaving groups bound to aromatic carbon atoms of the monomer with monomers comprising leaving groups selected from halogen, sulfonic acid or sulfonic ester, preferably bromine or iodine, bound to aromatic carbon atoms of the monomer in the presence of a palladium (0) or palladium (II) catalyst and a base.

Exemplary boronic esters have formula (XII):

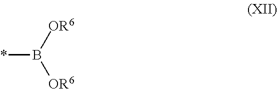

wherein R⁶ in each occurrence is independently a C₁₋₂₀ alkyl group, * represents the point of attachment of the boronic ester to an aromatic ring of the monomer, and the two groups R⁶ may be linked to form a ring.

In one embodiment, the polymer may be formed by polymerization of a monomer substituted with an n-dopant in order to form the first repeat unit, optionally with polymerization of monomers for forming one or more further repeat units.

In another embodiment, formation of the polymer comprises the step of polymerizing a monomer that is not substituted with an n-dopant to form a polymer comprising a precursor of the first repeat unit and the step of reacting the precursor of the first repeat unit with a reactant comprising the n-dopant to form the first repeat unit.

The precursor of the first repeat unit is substituted with a reactive group for reaction with the reactant comprising the n-dopant. This reactive group may be protected during polymerization to prevent any reaction of the reactive group that may otherwise occur during polymerization, followed by deprotection after polymerization to form a reactive precursor polymer.

The reactive precursor polymer may comprise a repeat unit of formula (Ir) that is reacted with an n-dopant group substituted with a reactive group capable of reacting with the repeat unit of formula (Ir):

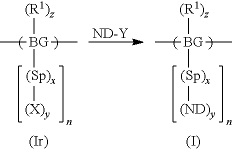

wherein X is a reactive group or, in the case where x is 1, Sp-X may comprise a reactive group; and Y is a reactive group. ND-Y is an n-dopant group substituted with a reactive group capable of reacting with the repeat unit of formula (Ir).

The reactive group X or the reactive group of Sp-X may be selected from one of reactive groups (i) and (ii) reactive group and Y is selected from the other of groups (i) and (ii) wherein group (i) is a leaving group, optionally halogen, preferably bromine or iodine, or a sulfonic ester group; and group (ii) a group selected from —OH, —SH, NH₂ or NHR¹¹ wherein R¹¹ is a C₁₋₁₀ hydrocarbyl group.

In one embodiment, X is H which together with an O atom of Sp forms a reactive group OH, and Y is a leaving group selected from bromine, iodine and sulfonic esters.

The reactive group may be a hydroxyl or hydroxide group that is directly bound to the backbone of the polymer or spaced apart therefrom by a spacer group.

### Activation

In the case where the polymer comprises an n-dopant substituent that does not dope the organic semiconductor spontaneously, n-doping may be effected by activation. Preferably, n-doping is effected after formation of a device comprising the layer containing the organic semiconductor and n-dopant, and optionally after encapsulation. Activation may be by excitation of the n-dopant and/or the organic semiconductor.

Exemplary activation methods are thermal treatment and irradiation.

Optionally, thermal treatment is at a temperature in the range 80° C. to 170° C., preferably 120° C. to 170° C. or 140° C. to 170° C.

Thermal treatment and irradiation as described herein may be used together.

For irradiation, any wavelength of light may be used, for example a wavelength having a peak in the range of about 200-700 nm.

Optionally, the peak showing strongest absorption in the absorption spectrum of the organic semiconductor is in the range of 400-700 nm. Preferably, the strongest absorption of the n-dopant is at a wavelength below 400 nm.

The present inventors have surprisingly found that exposure of a composition of an organic semiconductor and a polymer substituted with an n-dopant that does not spontaneously dope the organic semiconductor to electromagnetic radiation results in n-doping and that the electromagnetic radiation need not be at a wavelength that can be absorbed by the n-dopant.

The light emitted from the light source suitably overlaps with an absorption feature, for example an absorption peak or shoulder, of the organic semiconductor's absorption spectrum. Optionally, the light emitted from the light source has a peak wavelength within 25 nm, 10 nm or 5 nm of an absorption maximum wavelength of the organic semiconductor, however it will be appreciated that a peak wavelength of the light need not coincide with an absorption maximum wavelength of the organic semiconductor.

The extent of doping may be controlled by one or more of: the organic semiconductor/n-dopant ratio; the peak wavelength of the light; the duration of irradiation of the film; and the intensity of the light. It will be appreciated that excitation will be most efficient when a peak wavelength of the light coincides with an absorption maximum of the organic semiconductor.

Optionally, irradiation time is between 1 second and 1 hour, optionally between 1-30 minutes.

Preferably, the light emitted from the light source is in the range 400-700 nm. Preferably, the electromagnetic radiation has a peak wavelength greater than 400 nm, optionally greater than 420 nm, optionally greater than 450 nm. Optionally, there is no overlap between an absorption peak in the absorption spectrum of the n-dopant and the wavelength(s) of light emitted from the light source.

Optionally, the organic semiconductor has a LUMO level of no more than 3.2 eV from vacuum level, optionally no more than 3.1 or 3.0 eV from vacuum level.

Any suitable electromagnetic radiation source may be used to irradiate the film including, without limitation, fluorescent tube, incandescent bulb and organic or inorganic LEDs. Optionally, the electromagnetic radiation source is an array of inorganic LEDs. The electromagnetic radiation source may produce radiation having one or more than one peak wavelengths.

Preferably, the electromagnetic radiation source has a light output of at least 2000 mW, optionally at least 3000 mW, optionally at least 4000 mW.

Preferably, no more than 10% or no more than 5% of the light output of the electromagnetic radiation source is from radiation having a wavelength less than or equal to 400 nm, optionally less than or equal to 420 nm. Preferably, none of the light output has a wavelength of less than or equal to 400 nm, optionally less than or equal to 420 nm.

Inducing n-doping without exposure to short wavelength light, such as UV light, may avoid damage to the materials of the OLED.

The n-doped organic semiconductor may be an extrinsic or degenerate semiconductor.

In manufacture of an organic electronic device, such as an OLED as described in FIG. 1, activation may take place during device formation or after the device has been formed. Preferably, activation to cause n-doping takes place after the device has been formed and encapsulated. The device may be manufactured in an environment in which little or no spontaneous doping occurs, for example a room temperature environment wherein the n-dopant and organic semiconductor are exposed to little or no wavelengths of light that induce n-doping until after encapsulation of the device, for example an environment illuminated by light having a longer wavelength than that of the electromagnetic radiation source such as a clean room illuminated with yellow light.

In the case of an OLED as described in FIG. 1, a film 107 of the polymer substituted with the n-dopant and the organic semiconductor may be formed over organic light-emitting layer 105 and the cathode 109 may be formed over the film.

For activation by irradiation, the film may then irradiated through the anode 101, in the case of a device formed on a transparent substrate 101 and having a transparent anode 103, such as ITO, or the film may be irradiated through the cathode 109 in the case of a device with a transparent cathode. The wavelength used to induce n-doping may be selected to avoid wavelengths that are absorbed by layers of the device between the electromagnetic radiation source and the film.

### Light-Emitting Layers

The OLED 100 may contain one or more light-emitting layers.

Light-emitting materials of the OLED 100 may be fluorescent materials, phosphorescent materials or a mixture of fluorescent and phosphorescent materials. Light-emitting materials may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12 1737-1750, 2000, the contents of which are incorporated herein by reference. Light-emitting layer 107 may comprise a host material and a fluorescent or phosphorescent light-emitting dopant. Exemplary phosphorescent dopants are row 2 or row 3 transition metal complexes, for example complexes of ruthenium, rhodium, palladium, rhenium, osmium, iridium, platinum or gold.

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A light-emitting layer may contain a mixture of more than one light-emitting material, for example a mixture of light-emitting materials that together provide white light emission. A plurality of light-emitting layers may together produce white light.

A fluorescent light-emitting layer may consist of a light-emitting material alone or may further comprise one or more further materials mixed with the light-emitting material. Exemplary further materials may be selected from hole-transporting materials; electron-transporting materials and triplet-accepting materials, for example a triplet-accepting polymer as described in WO 2013/114118, the contents of which are incorporated herein by reference.

### Cathode

The cathode may comprise one or more layers. Preferably, the cathode comprises or consists of a layer in contact with the electron injecting layer that comprises or consists of one or more conductive materials. Exemplary conductive materials are metals, preferably metals having a work function of at least 4 eV, optionally aluminium, copper, silver or gold or iron. Exemplary non-metallic conductive materials include conductive metal oxides, for example indium tin oxide and indium zinc oxide, graphite and graphene. Work functions of metals are as given in the CRC Handbook of Chemistry and Physics, 12-114, 87^{th} Edition, published by CRC Press, edited by David R. Lide. If more than one value is given for a metal then the first listed value applies.

The cathode may be opaque or transparent. Transparent cathodes are particularly advantageous for active matrix devices because emission through a transparent anode in such devices is at least partially blocked by drive circuitry located underneath the emissive pixels.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Hole-Transporting Layer

A hole transporting layer may be provided between the anode 103 and the light-emitting layer 105.

The hole-transporting layer may be cross-linked, particularly if an overlying layer is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

If present, a hole transporting layer located between the anode and the light-emitting layer 105 preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer in order to provide a small barrier to hole transport between these layers.

Preferably a hole-transporting layer, more preferably a crosslinked hole-transporting layer, is adjacent to the light-emitting layer 105.

A hole-transporting layer may consist essentially of a hole-transporting material or may comprise one or more further materials. A light-emitting material, optionally a phosphorescent material, may be provided in the hole-transporting layer.

A phosphorescent material may be covalently bound to a hole-transporting polymer as a repeat unit in the polymer backbone, as an end-group of the polymer, or as a side-chain of the polymer. If the phosphorescent material is provided in a side-chain then it may be directly bound to a repeat unit in the backbone of the polymer or it may be spaced apart from the polymer backbone by a spacer group. Exemplary spacer groups include C₁₋₂₀ alkyl and aryl-C₁₋₂₀ alkyl, for example phenyl-C₁₋₂₀ alkyl. One or more carbon atoms of an alkyl group of a spacer group may be replaced with O, S, C═O or COO.

Emission from a light-emitting hole-transporting layer and emission from light-emitting layer 105 may combine to produce white light.

### Hole Injection Layers

A conductive hole injection layer, which may be formed from a conductive organic or inorganic material, may be provided between the anode 103 and the light-emitting layer 105 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Encapsulation

In the case where the polymer as described herein is substituted with an n-dopant that does not spontaneously dope the organic semiconductor, the n-dopant is preferably activated to cause n-doping as described herein after encapsulation of the device containing the film to prevent ingress of moisture and oxygen.

Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

The substrate on which the device is formed preferably has good barrier properties such that the substrate together with the encapsulant form a barrier against ingress of moisture or oxygen. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

### Formulation Processing

Light-emitting layer 105 and electron-injecting layer 107 may be formed by any method including evaporation and solution deposition methods. Solution deposition methods are preferred.

Formulations suitable for forming light-emitting layer 105 and electron-injecting layer 107 may each be formed from the components forming those layers and one or more suitable solvents.

Preferably, light-emitting layer 105 is formed by depositing a solution in which the solvent is one or more non-polar solvent materials, optionally benzenes substituted with one or more substituents selected from C₁₋₁₀ alkyl and C₁₋₁₀ alkoxy groups, for example toluene, xylenes and methylanisoles, and mixtures thereof.

Optionally, the film comprising the organic semiconductor and the polymer comprising n-dopant substituents to form the electron-injecting layer 107 is formed by depositing a solution.

Preferably, the electron-injecting layer is formed from a polar solvent, optionally a protic solvent, optionally water or an alcohol; dimethylsulfoxide; propylene carbonate; or 2-butanone which may avoid or minimise dissolution of the underlying layer if the materials of the underlying layer are not soluble in polar solvents.

Exemplary alcohols include methanol ethanol, propanol, butoxyethanol and monofluoro-, polyfluoro- or perfluoro-alcohols, optionally 2,2,3,3,4,4,5,5-Octafluoro-1-pentanol.

Particularly preferred solution deposition techniques including printing and coating techniques such spin-coating, inkjet printing and lithographic printing.

Coating methods are particularly suitable for devices wherein patterning of the light-emitting layer is unnecessary—for example for lighting applications or simple monochrome segmented displays.

Printing methods are particularly suitable for high information content displays, in particular full colour displays. A device may be inkjet printed by providing a patterned layer over the anode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, slot die coating, roll printing and screen printing.

### Applications

The doped organic semiconductor layer has been described with reference to the electron-injection layer of an organic light-emitting device, however it will be appreciated that the layer formed as described herein may be used in other organic electronic device, for example as an electron-extraction layer of an organic photovoltaic device or organic photodetector; as an auxiliary electrode layer of a n-type organic thin film transistor or as an n-type semiconductor in a thermoelectric generator.

### Measurements

UV-visible absorption spectra of pristine and n-doped acceptor materials as described herein were measured by spin-coating onto glass substrates, as blend with the dopant. The film thicknesses were in the range of 20-100 nm.

After spin-coating and drying, the polymer films were encapsulated in a glove box, in order to exclude any contact of the n-doped films with air.

After the encapsulation, UV-vis absorption measurements were conducted with a Carey-5000 Spectrometer, followed by successive exposures to visible light and repeat UV-VIS measurements.

HOMO, SOMO and LUMO levels as described anywhere herein are as measured by square wave voltammetry.

### Equipment:

CHI660D Electrochemical workstation with software (IJ Cambria Scientific Ltd))

### CHI 104 3 mm Glassy Carbon Disk Working Electrode (IJ Cambria Scientific Ltd))

Platinum wire auxiliary electrode

### Reference Electrode (Ag/AgCl) (Havard Apparatus Ltd)

### Chemicals

Acetonitrile (Hi-dry anhydrous grade-ROMIL) (Cell solution solvent)
Toluene (Hi-dry anhydrous grade) (Sample preparation solvent)
Ferrocene—FLUKA (Reference standard)
Tetrabutylammoniumhexafluorophosphate—FLUKA) (Cell solution salt)

### Sample Preparation

The acceptor polymers were spun as thin films (˜20 nm) onto the working electrode; the dopant material was measured as a dilute solution (0.3 w %) in toluene.

### Electrochemical Cell

The measurement cell contains the electrolyte, a glassy carbon working electrode onto which the sample is coated as a thin film, a platinum counter electrode, and a Ag/AgCl reference glass electrode. Ferrocene is added into the cell at the end of the experiment as reference material (LUMO (ferrocene)=−4.8 eV).

### Examples

### Intermediate Compound 1

Intermediate Compound 1 was prepared according to Scheme 1:

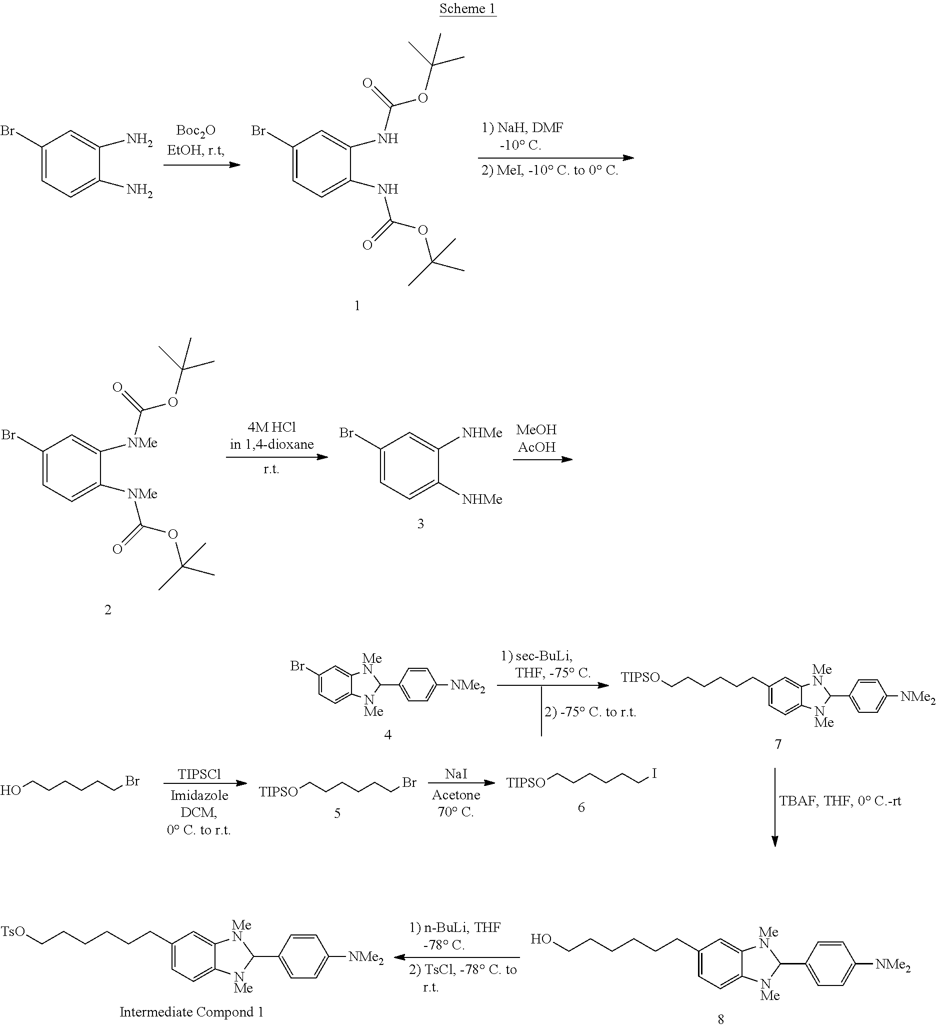

### Di-tert-butyl (4-bromo-1,2-phenylene)dicarbamate (1)

1,2-diamino-4-bromobenzene (450 g, 2.406 mol) was dissolved in ethanol (6000 mL). Di-tert-butyl dicarbonate (2100 g, 9.625 mol) was added portion wise at room temperature over 2 hours. The reaction mixture was stirred at room temperature for 16 hours. The reaction mixture was diluted with water (6000 mL) and stirred for 1 hour. The reaction mixture was filtered. The solid was dissolved in methanol (6000 mL) and precipitated out by adding water (5000 mL) and slurry was filtered. The solid was stirred with cold methanol (2200 mL) for 30 min, filtered and air dried for 4 hours to yield 700 g of Di-tert-butyl (4-bromo-1,2-phenylene)dicarbamate, 99.8% pure by HPLC, 75% yield.

¹H-NMR (400 MHz, CDCl3): δ [ppm] 1.51-1.61 (m, 18H), 6.57 (br, s, 1H), 6.76 (br, s, 1H), 7.22 (dd, J=2.19, 8.58 Hz, 1H), 7.32-7.35 (m, 1H), 7.76-7.77 (m, 1H).

### Di-tert-butyl (4-bromo-1,2-phenylene)bis(methylcarbamate) (2)

Sodium hydride (60% in mineral oil, 51.67 g, 1.2919 mol) was dissolved in N,N-dimethylformamide (500 mL) at −10° C. Di-tert-butyl (4-bromo-1,2-phenylene) dicarbamate (1) (200 g, 0.5167 mol) in N,N-dimethylformamide (1000 mL) was added to it over 20 min maintaining the internal temperature at −10° C. Methyl iodide (162 mL, 2.583 mol) was added over 30 min to the reaction mixture maintaining internal temperature at −10° C. Reaction was then stirred at −10° C. to 0° C. for 40 min and quenched with ice cold water (2000 mL). Mixture was stirred between 0° C. and 5° C. for 30 min. The slurry was filtered and solid was purified by silica gel column chromatography using 18% EtOAc in hexane as eluent to obtain 220 g of Di-tert-butyl (4-bromo-1,2-phenylene)bis(methylcarbamate) (2) as a white solid, 99.24% pure by HPLC, 77% yield.

¹H-NMR (400 MHz, CDCl3): δ [ppm] 1.38-1.52 (m, 18H), 3.09 (s, 6H), 7.06-7.14 (m, 1H), 7.37-7.39 (m, 2H).

### 4-Bromo-N¹,N²-dimethylbenzene-1,2-diamine (3)

Di-tert-butyl (4-bromo-1,2-phenylene)bis(methylcarbamate) (2) (291 g, 0.7006 mol) was dissolved in 1,4-dioxane (1500 mL). 4M HCl in 1,4-dioxane (1250 mL) was added to the solution at room temperature over 30 min. Reaction mixture stirred for 16 hours and ethyl acetate (1000 mL) was added. Mixture was stirred for 30 min and filtered. The solid was washed with ethyl acetate (300 mL). The solid was added to an aqueous solution of 10% NaHCO₃ (1500 mL) and stirred for 30 min. The slurry was filtered and the solid was dissolved in ethyl acetate (1200 mL) and filtered through a silica plug eluted with ethyl acetate. Filtrate was concentrated to yield 114 g of 4-Bromo-N¹,N²-dimethylbenzene-1,2-diamine (3) as a pale brown solid, 99.68% pure by HPLC, 76% yield.

¹H-NMR (400 MHz, CDCl3): δ [ppm] 2.67 (m, 6H), 4.7 (br, 1H), 4.89 (br, 1H), 6.29 (d, J=8.0 Hz, 1H), 6.41 (s, 1H), 6.65 (m, 1H).

### Intermediate (4)

4-N,N-Dimethyl amino benzaldehyde (29 g, 0.194 mol) was dissolved in dry methanol (210 mL), nitrogen was bubbled into the solution for 40 min. 4-Bromo-N¹,N²-dimethylbenzene-1,2-diamine (3) (42 g, 0.195 mol) was added and nitrogen was bubbled into the solution for 10 min. Glacial Acetic acid (20 mL) was added and mixture was stirred at room temperature for 3 h. The reaction mixture was cooled to 0° C. and the solid was collected by filtration. It was washed with cold methanol (80 mL) and dried under vacuum to yield 62 g of Intermediate (4) as a white solid, 99.66% pure by HPLC, 92% yield.

¹H-NMR (400 MHz, CD3OD: δ [ppm] 2.5 (s, 6H), 2.98 (s, 6H), 4.82 (s, 1H), 6.27 (m, 1H), 6.47 (s, 1H), 6.7 (m, 1H), 6.82 (d, J=6.96 Hz, 2H), 7.38 (d, J=6.96 Hz, 2H)

### ((6-bromohexyl)oxy)triisopropylsilane (5)

Imidazole (20.3 g, 0.298 mol) was added to a solution of 6-bromohexanol (27.0 g, 0.179 mol) in dichloromethane (540 ml) at 0° C. Chlorotriisopropylsilane (63.5 ml, 0.298 mol) was added drop wise to the solution at 0° C. and reaction was stirred at room temperature overnight. It was quenched by adding water (100 ml) at 0° C. Phases were separated and organic phase was washed with water (3×150 ml), dried over MgSO₄ and concentrated under reduced pressure. Residue was purified by vacuum distillation to yield 35.3 g of ((6-bromohexyl)oxy)triisopropylsilane (5) as a colourless oil, 70% yield.

¹H-NMR (600 MHz, CDCl3): δH [ppm] 1.04-1.10 (m, 21H), 1.39 (m, 2H), 1.46 (m, 2H), 1.55 (m, 2H), 1.87 (quint, 2H), 3.41 (t, 2H), 3.68 (t, 2H).

### ((6-iodohexyl)oxy)triisopropylsilane (6)

Sodium iodide (44.42 g, 0.296 mol) was added portion wise to a solution of ((6-bromohexyl)oxy)triisopropylsilane (5) (20.0 g, 0.059 mol) in acetone (200 ml). The mixture was stirred at 70° C. for 1 hour and cooled down to room temperature. Reaction was filtered and acetone solution was concentrated under reduced pressure. Toluene (200 ml) was added to the residue, slurry was stirred for 5 min and filtered. Solid was washed with toluene and filtrate was washed with 10 wt % aqueous sodium acetate, water, dried over MgSO₄ and concentrated under reduced pressure. Residue was purified by vacuum distillation to yield 12.0 g of ((6-iodohexyl)oxy)triisopropylsilane (6) as a colourless oil, 53% yield.

¹H-NMR (600 MHz, CDCl3): δH [ppm] 1.04-1.10 (m, 21H), 1.35-1.45 (m, 4H), 1.55 (quint, 2H), 1.84 (quint, 2H), 3.19 (t, 2H), 3.68 (t, 2H).

### Intermediate (7)

Nitrogen was bubbled for 30 min into a solution of Intermediate (4) (12.70 g, 36.7 mmol) in dry tetrahydrofuran (130 ml). Solution was cooled down to −75° C. Sec-butyl lithium (1.4M in cyclohexane, 34 ml, 47.7 mmol) was added drop wise and mixture was stirred for 30 min at −75° C. ((6-iodohexyl)oxy)triisopropylsilane (6) (9.51 g, 24.7 mmol) was added drop wise and mixture was stirred for 75 min at −75° C. Extra ((6-iodohexyl)oxy)triisopropylsilane (6) (7.41 g, 19.3 mmol) was added drop wise and mixture was stirred for 3 hours at −75° C. The reaction mixture was stirred overnight while warming to room temperature. It was quenched by adding water (60 ml) drop wise at 5° C. Tetrahydrofuran was removed under reduced pressure, residue was extracted with toluene (3×30 ml). Combined organic phases were washed with water (2×50 ml), dried over MgSO₄ and concentrated under reduced pressure to yield 21.9 g of Intermediate (7) as an orange oil, 70% pure by NMR.

¹H-NMR (600 MHz, CDCl3): δH [ppm] 1.04-1.10 (m, 21H), 1.38 (m, 4H), 1.55 (m, 2H), 1.60 (m, 2H), 2.49-2.56 (m, 8H), 3.0 (s, 6H), 3.68 (t, 2H), 4.70 (s, 1H), 6.26 (s, 1H), 6.33 (d, J=7.6 Hz, 1H), 6.5 (dd, J=1.2 Hz, 7.6 Hz, 1H), 6.75 (m, 2H), 7.42 (m, 2H).

### Intermediate (8)

A solution of tertrabutyl ammonium fluoride (24.0 g, 66.4 mmol in tetrahydrofuran (40 ml) was added drop wise to a solution of Intermediate (7) (21.9 g, 29.3 mmol) in tetrahydrofuran (150 ml) at 0° C. It was stirred for 1 hour and tetrahydrofuran was removed under reduced pressure. Residue was extracted with dichloromethane. Organic phase was washed with water, dried over MgSO₄ and concentrated under reduced pressure. Volatile impurities were removed by vacuum distillation. Residue was dissolved in a mixture of dichloromethane:heptane (4:6) and filtered through a basic alumina plug, eluted with dichloromethane:heptane (4:6) followed by ethyl acetate. Fractions containing the desired product were combined and concentrated under reduced pressure to yield 9.1 g of Intermediate (8) as an orange oil, 84% yield.

¹H-NMR (600 MHz, CDCl3): δH [ppm] 1.38 (m, 4H), 1.54-1.66 (m, 4H), 2.49-2.56 (m, 8H), 2.99 (s, 6H), 3.65 (m, 2H), 4.71 (s, 1H), 6.26 (d, J=1.2 Hz, 1H), 6.33 (d, J=7.4 Hz, 1H), 6.50 (dd, J=1.2 Hz, 7.6 Hz, 1H), 6.75 (m, 2H), 7.42 (m, 2H).

### Intermediate Compound 1

n-Butyl lithium (7.8 ml, 19.6 mmol) was added to a solution of Intermediate (8) (7.2 g, 19.6 mmol) in dry tetrahydrofuran (140 ml) at −78° C. Solution was stirred for 15 min at −78° C. and tosyl chloride (3.73 g, 19.6 mmol) was added portion wise. Mixture was stirred for 30 min at −78° C. and tosyl chloride (0.373 g, 1.96 mmol) was added and stirring was prolonged for 30 min at −78° C. Mixture was warmed up to 0° C., then cooled down to −60° C. and tosyl chloride (0.373 g, 1.96 mmol) was added. Mixture was warmed up to 0° C. over 30 min and quenched by adding 1% aqueous NH₄OH (40 ml) followed by adding 3% aqueous NH₄OH (10 ml). Tetrahydrofuran was removed under reduced pressure and residue was extracted with toluene (3×). Combined organic phases were washed with water (3×) dried over MgSO₄ and concentrated under reduced pressure. Residue was dissolved in a mixture of dichloromethane:heptane (8:2) and filtered through a basic alumina plug, eluted with dichloromethane:heptane (8:2). Fractions containing the desired product were combined and concentrated under reduced pressure to yield 6.8 g of Intermediate Compound 1 as an orange oil, 64% yield.

¹H-NMR (600 MHz, CDCl3): δH [ppm] 1.24-1.37 (m, 6H), 1.55 (m, 2H), 1.65 (2H), 2.46 (m, 5H), 2.52 (s, 3H), 2.53 (s, 3H), 2.99 (s, 6H), 4.03 (t, 2H), 4.71 (s, 1H), 6.23 (d, J=1.2 Hz, 1H), 6.32 (d, J=7.6 Hz, 1H), 6.46 (dd, J=1.2 Hz, 7.6 Hz, 1H), 6.75 (m, 2H), 7.34 (d, J=8.1 Hz, 2H), 7.42 (m, 2H), 7.79 (d, J=8.1 Hz, 2H).

### Intermediate Compound 2

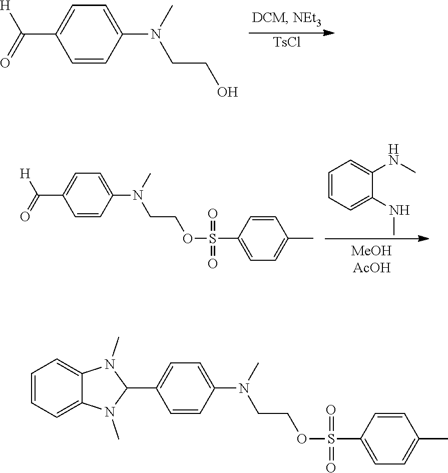

### Intermediate Compound 2 Stage 1

N-Methyl-N-(2-hydroxyethyl)-4-aminobenzaldehyde (8.00 g, 44.6 mmol) was dissolved in dichloromethane (100 ml) and cooled to 0° C. Triethylamine (10.38 g, 14.2 ml, 102.7 mmol) was added and nitrogen was bubbled into the reaction mixture for 5 minutes. Tosylchloride (10.21 g, 53.6 mmol) was added portion wise over 20 minutes and the reaction was left to warm up to room temperature overnight. The reaction mixture was cooled to 0° C.; water (5 ml) was added drop wise followed by the drop wise addition of 10% aq. HCl until pH 2 is reached. Water (50 ml) was added and the aqueous phase was extracted twice with dichloromethane. The organic phase was washed once with water and twice with 3% aq. NH₄OH, dried over MgSO₄ and concentrated to dryness under reduced pressure. The crude product was filtered through a silica plug (0.70 mm×50 mm) eluted with dichloromethane followed by dichloromethane:ethyl acetate (85:15). A first fraction was concentrated to dryness under reduced pressure, triturated with MeOH (20 ml), filtered and air-dried to afford Intermediate Compound 2 Stage 1 as a pink solid, 2.95 g, 99.14% pure by HPLC, 20% yield. The second fraction was concentrated to dryness under reduced pressure to afford Intermediate Compound 2 Stage 1 as a pink solid, 7.72 g, 97.53% pure by HPLC, 52% yield.

¹H-NMR (600 MHz, CDCl3): δH [ppm] 2.40 (s, 3H), 3.01 (s, 3H), 3.72 (t, J=6.0 Hz, 2H), 4.21 (d, J=5.8 Hz, 2H), 6.59 (d, J=9.0 Hz, 2H), 7.24 (d, J=8.2 Hz, 2H), 7.66-7.70 (m, 4H), 9.75 (s, 1H).

### Intermediate Compound 2

Intermediate Compound 2 Stage 1 (2.508 g, 7.52 mmol) and N,N′-Dimethyl-1,2-phenylenediamine (1.103 g, 8.10 mmol) were suspended in anhydrous methanol (15 ml) and nitrogen was bubbled into the slurry for 10 minutes. Acetic acid (0.15 ml) was added and the reaction was stirred overnight at room temperature after which tetrahydrofuran (8 ml) was added and the reaction mixture was stirred for an additional 6 hours at room temperature. The mixture was cooled to 0° C. and stirred for 30 minutes. The off-white precipitate was filtered and washed with methanol (30 ml), air dried to afford Intermediate Compound 2 as an off-white solid, 1.94 g, 94.2% pure by HPLC, 53% yield.

¹H-NMR (600 MHz, CDCl3): δH [ppm] 2.43 (s, 3H), 2.54 (s, 6H), 2.93 (s, 3H), 3.65 (t, J=6.0 Hz, 2H), 4.20 (t, J=6.0 Hz, 2H), 4.77 (s, 1H), 6.40-6.43 (m, 2H), 6.61 (d, J=8.5 Hz, 2H), 6.69-6.71 (m, 2H), 7.30 (d, J=8.6 Hz), 7.37 (d, J=8.5 Hz, 2H), 7.74 (d, J=8.3 Hz, 2H).

### Monomer Example 1

Monomer Example 1 was prepared according to Scheme 2:

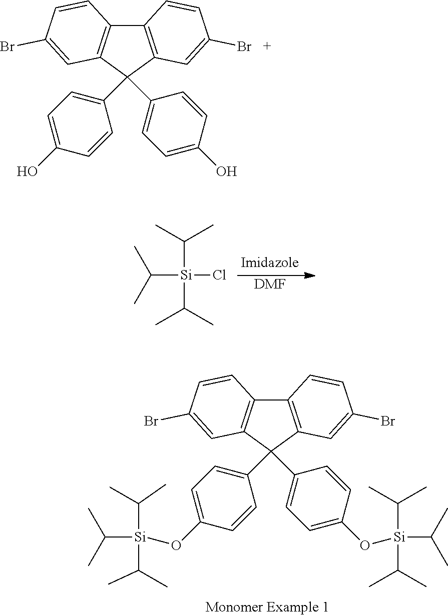

4,4′-(2,7-dibromo-9H-fluorene-9,9-diyl)diphenol (147.0 g, 0.289 mol) was dissolved in N,N-dimethylformamide (1500 mL). Imidazole (118.13 g, 1.735 mol) was added followed by the drop wise addition of triisopropylsilyl chloride (290.4 g, 1.506 mol). Mixture was stirred at room temperature for 20 h. It was quenched by the addition of methanol (2500 mL) and mixture was stirred for 2 hours. The slurry was filtered and solid was washed with methanol (500 mL) and then suck dried for 3 hours. Solid was purified by column chromatography (230-400 silica gel) using hexane as eluent to get 165 g of monomer example 1 as a white solid, 99.95% pure by HPLC, 70% yield.

¹H-NMR (400 MHz, CDCl3): δ [ppm] 1.1 (d, J=7.20 Hz, 36H), 1.24 (m, 6H), 6.76 (d, J=8.4 Hz, 4H), 7.99 (d, J=8.4 Hz, 4H), 7.47 (d, J=3.2 Hz, 2H), 7.48 (s, 2H), 7.57 (d, J=7.6 Hz, 2H)

### Protected Precursor Polymer Examples

Polymers were prepared by Suzuki polymerisation as described in WO 00/53656 of the following monomers:

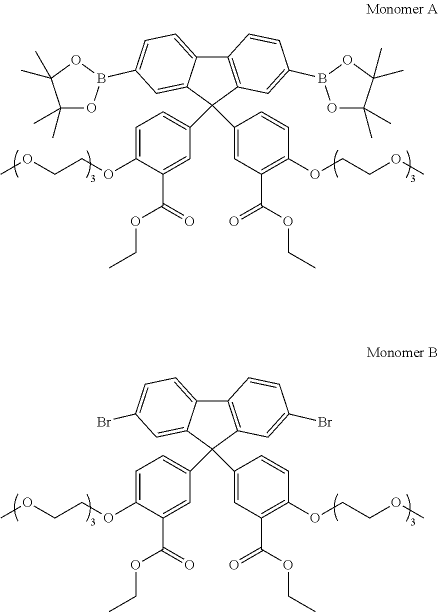

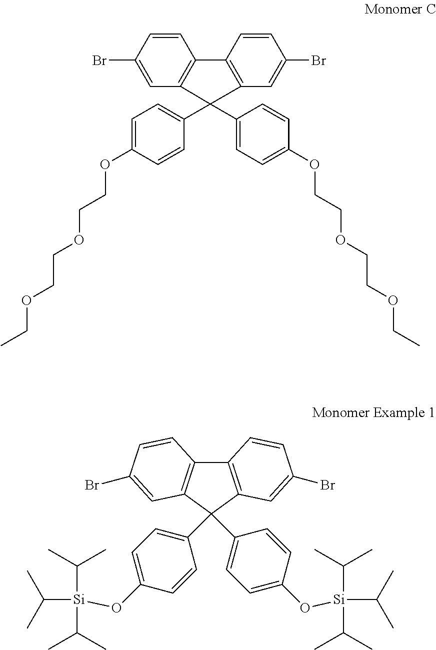

| | Monomers | | | | | |
|---|---|---|---|---|---|---|
| Polymer | (mol %) | Mz | Mw | Mp | Mn | Pd |
| Precursor | A (50), C (40), | 61,000 | 44,000 | 57,000 | 25,000 | 1.8 |
| Polymer | Example 1 (10) | | | | | |
| Example 1 | | | | | | |
| Precursor | A (50), B (30), | 48,000 | 39,000 | 55,000 | 26,000 | 1.52 |
| Polymer | Example 1 (20) | | | | | |
| Example 2 | | | | | | |

The protected repeat units of the protected precursor polymers were reacted according to the following reaction scheme to form a reactive precursor polymer:

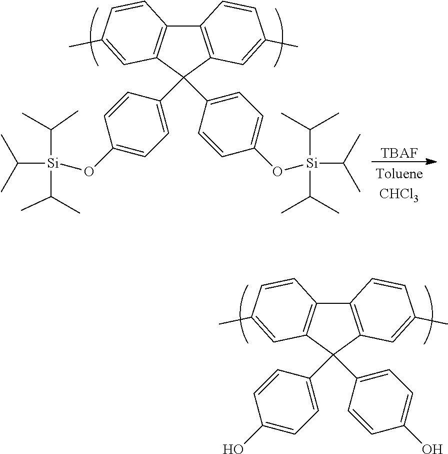

### Reactive Precursor Polymer Example 1

A solution of 2.33 g of Precursor Polymer Example 1 dissolved in 58 ml of degassed toluene was cooled down to 0° C. A solution of tetrabutyl ammonium fluoride (TBAF, 0.367 g, 2.40 mmol) in 5 ml of degassed chloroform was added to it drop wise. Solution was allowed to warm up to room temperature and stirred overnight. 100 ml of water was added and mixture was stirred for 5 min. The mixture was poured slowly into 800 ml of methanol and slurry was stirred for 30 min Slurry was filtered and polymer cake was washed with 75 ml of methanol. It was then dried in vacuum oven at 50° C. for 24 hrs to yield 1.31 g of polymer Reactive Polymer Example 1, 70% yield.

### Reactive Precursor Polymer Example 2

Reactive Polymer Example 2 was prepared from Precursor Polymer Example 2 using the process described for Reactive Polymer Example 1.

2.62 g of Precursor Polymer Example 2 in 106 ml of toluene was reacted with TBAF (0.748 g, 2.86 mmol) in 6.5 ml of chloroform. 2.14 g of Reactive Polymer Example 2 was obtained (89%).

The reactive repeat units were reacted with Intermediate Compound 1 to form exemplary polymers substituted with n-dopant precursors according to the following reaction scheme:

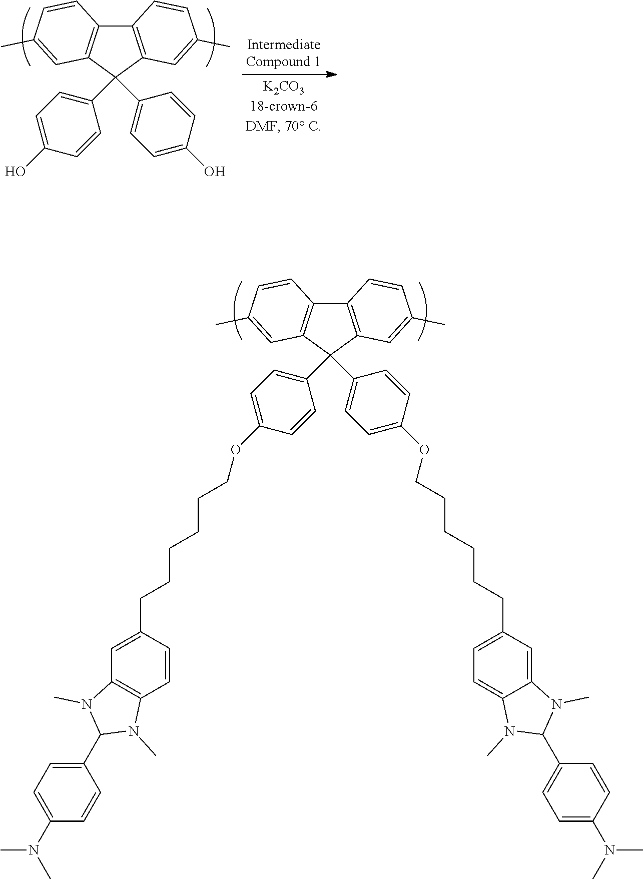

### Polymer Example 1

A mixture of Reactive Polymer Example 1 (1.88 g, 2.97 mmol), potassium carbonate (0.328 g, 2.38 mmol) and 18-crown-6 (0.028 g, 0.104 mmol) in 95 ml N,N-dimethylformamide was heated up to 70° C. while nitrogen was bubbling in the liquid. It was stirred until all the polymer dissolved. A solution of Intermediate Compound 1 (0.028 g, 0.104 mmol) in 19 ml of N,N-dimethylformamide was added to the solution. The reaction mixture was stirred for 10 hours and cooled down to room temperature. Nitrogen was bubbled into 750 ml methanol and reaction mixture was added drop wise to it. The resultant slurry was stirred for 10 minutes and filtered. Nitrogen was bubbled into 300 ml methanol and polymer cake was added to it, the slurry was stirred for 10 minutes and filtered. The product was dried in vacuum oven at 40° C. overnight to yield 1.75 g of Polymer Example 1 (84%).

### Polymer Example 2

Polymer Example 2 was prepared from Reactive Polymer Example 2 using the process described for Polymer Example 1.

2.62 g of Reactive Polymer Example 2 was reacted with potassium carbonate (0.658 g, 4.76 mmol), 18-crown-6 (0.055 g, 0.208 mmol) Intermediate Compound 1 (1.55 g, 2.98 mmol) in 122 ml of N,N-dimethylformamide. 2.31 g of Polymer Example 2 was obtained (95%).

### Device Examples

Electron-only devices having the layer structure ITO/OSC+n-dopant/silver were formed on a glass substrate in which OSC+n-dopant layer was formed by spin-coating an o-xylene solution of a polymer comprising n-dopant substituents with an organic semiconductor in a glove-box.

The organic semiconductor was F8BT:

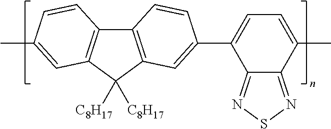

The n-dopant mixed with F8BT comprised 50 mol % of Fluorene Unit A, illustrated below, 40 mol % of Fluorene Unit B of formula (Vb) wherein each R¹ is a hydrocarbyl group; and n-dopant Unit 1, illustrated below:

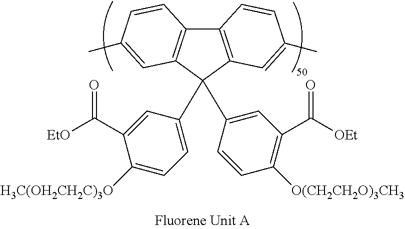

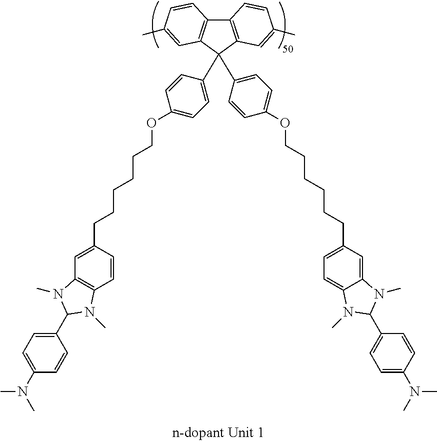

After drying at 80° C. for 10 min, a layer of 100 nm silver was thermally evaporated onto the F8BT/n-dopant polymer mixture, and the device was then encapsulated.

For the purpose of comparison, a device having a layer consisting of F8BT only was formed.

Treatments of the devices following encapsulation are shown in Table 1.

TABLE 1

| | Organic layer | Organic layer | |
|---|---|---|---|
| Device | components (wt %) | thickness (nm) | Treatment |
| 1 (Comparative) | F8BT | 100 | none |
| 2a | F8BT:Polymer dopant | 80 | none |
| | (60:40) | | |
| 2b | F8BT:Polymer dopant | 80 | Blue light |
| | (60:40) | | irradiation |
| | | | for 600 |
| | | | seconds at |
| | | | room |
| | | | temperature |
| 3a | F8BT:Polymer dopant | 80 | |
| | (60:40) | | |
| 3b | F8BT:Polymer dopant | 80 | Blue light |
| | (60:40) | | irradiation |
| | | | for 600 |
| | | | seconds at |
| | | | 80 C. |

The blue light source used was the ENFIS UNO Air Cooled Light Engine:

http://docs-europe.electrocomponents.com/webdocs/0913/0900766b8091353d.pdf

With reference to FIG. 2, for Device (1) here is a low level of electron injection (<10⁻² mA/cm²), even at 8V, from the evaporated Ag cathode into the non-doped F8BT acceptor polymer which may be due to a large barrier to electron injection at the Ag-F8BT interface.

Referring now to devices with doped F8BT:PD (60:40 w %) (Devices 2a and 3a), addition of 40 w % of the polymer carrying pendant dopant results in improved electron injection, particularly at moderate forward drive voltages (the current density increases by 4 orders of magnitude at +3V), although J-V characteristics remain asymmetric (e.g. at −4V vs. +4V).

Upon irradiation with blue light at room temperature (Device 2b): a further increase in current density is achieved, particularly at reverse bias and at high forward bias. This is consistent with an increased level of bulk doping due to photoactivation of the n-doping of F8BT by the polymer dopant.

When the irradiation with blue light is performed at elevated temperature (Device 3b), the doping effect is much larger than light irradiation at room temperature. In particular, the current densities at reverse bias increase strongly, and the J-V characteristics become more symmetrical, indicative of a high level of n-doping.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A charge-transfer salt formed from an organic semiconductor n-doped by a polymer comprising a first repeat unit substituted with at least one group comprising at least one n-dopant.

2. A charge-transfer salt according to claim 1 wherein the n-dopant is a 2,3-dihydro-benzoimidazole group.

3. A charge-transfer salt according to claim 1 wherein the n-dopant is (4-(1,3-dimethyl-2,3-dihydro-1H-benzoimidazol-2-yl)phenyl)dimethylamine.

4. A charge-transfer salt according to claim 1 wherein the polymer comprises a repeat unit of formula (I): 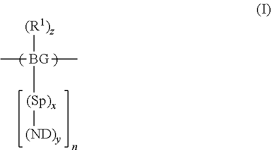
wherein:
BG is a backbone group;
Sp is a spacer group;
ND is an n-dopant;
R¹ is a substituent;
x is 0 or 1;
y is at least 1; and
z is 0 or a positive integer; and
n is at least 1.

5. A charge-transfer salt according to claim 4 wherein BG is a C₆₋₂₀ arylene group.

6. A charge-transfer salt according to claim 5 wherein BG is fluorene.

7. (canceled)

8. A charge-transfer salt according to claim 1 wherein the polymer comprises or consists of one or more further repeat units selected from C₆₋₂₀ arylene repeat units that may be unsubstituted or substituted with one or more substituents.

9. (canceled)

10. A charge-transfer salt according to claim 1 wherein the organic semiconductor comprises a bond selected from a C═N group, a nitrile group, a C═O group and a C═S group.

11. A charge-transfer salt according to claim 1 wherein the organic semiconductor has a lowest unoccupied molecular orbital level of no more than 3.2 eV from vacuum level.

12. A charge-transfer salt according to claim 1 wherein the organic semiconductor is mixed with the polymer comprising the first repeat unit.

13. (canceled)

14. A charge-transfer salt according to claim 12 wherein the organic semiconductor is a polymer.

15. (canceled)

16. A charge-transfer salt according to claim 1 wherein the organic semiconductor is a repeat unit in the backbone of the polymer comprising the first repeat unit.

17. (canceled)

18. A method of forming a charge-transfer salt according to claim 12 comprising the step of activating the mixture to cause the n-dopant to dope the organic semiconductor.

19. A method according to claim 18 comprising the step of mixing the organic semiconductor with the polymer to form the mixture wherein the mixture is formed in air.

20. (canceled)

21. An organic electronic device comprising a layer comprising a charge-transfer salt according to claim 1.

22. An organic electronic device according to claim 21 wherein the organic electronic device is an organic light-emitting device comprising an anode, a cathode and a light-emitting layer between the anode and the cathode and wherein the layer comprising the charge-transfer salt is an electron injection layer between the light-emitting layer and the cathode.

23. (canceled)

24. A method of forming an organic electronic device according to claim 21 wherein the layer comprising the charge-transfer salt is formed by forming a layer comprising or consisting of a mixture of the organic semiconductor and the polymer, or comprising or consisting of a polymer comprising a first repeat unit in a backbone of the polymer substituted with at least one group comprising at least one n-dopant a polymer and an organic semiconductor repeat unit in the polymer backbone, and activating the layer to cause the n-dopant to dope the organic semiconductor.

25. (canceled)

26. A polymer comprising a repeat unit of formula (I): 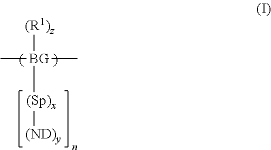
wherein:
BG is a backbone group;
Sp is a spacer group;
ND is an n-dopant;
R¹ is a substituent;
x is 0 or 1;
y is at least 1; and
z is 0 or a positive integer; and
n is at least 1.

27. A polymer according to claim 26 wherein ND comprises a 2,3-dihydro-benzoimidazole group.

28. A method of forming a polymer according to claim 26, the method comprising the step of reacting a precursor polymer comprising a reactive repeat unit of formula (Ir) with a compound of formula ND-Y 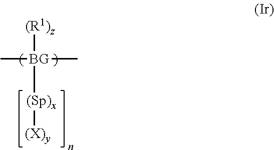
wherein X is a reactive group or wherein Sp-X comprises a reactive group; and Y is a reactive group.
